(19) United States
(12) Patent Application Publication
(10) Pub. No.: US 2013/0069035 A1
(43) Pub. Date: Mar. 21, 2013

(54) SEMICONDUCTOR LIGHT EMITTING DEVICE

(71) Applicants: Takuo KIKUCHI, Kanagawa-ken (JP); Hidehiko YABUHARA, Kanagawa-ken (JP); Chiyang CHANG, Kanagawa-ken (JP)

(72) Inventors: Takuo KIKUCHI, Kanagawa-ken (JP); Hidehiko YABUHARA, Kanagawa-ken (JP); Chiyang CHANG, Kanagawa-ken (JP)

(73) Assignee: KABUSHIKI KAISHA TOSHIBA, Tokyo (JP)

(21) Appl. No.: 13/616,241

(22) Filed: Sep. 14, 2012

(30) Foreign Application Priority Data
Sep. 21, 2011 (JP) 2011-206425

(51) Int. Cl. H01L 33/06

(52) U.S. Cl. 257/13; 257/E33.008

(57) ABSTRACT

According to one embodiment, a semiconductor light emitting device includes an n-type semiconductor layer, a p-type semiconductor layer, a light emitting layer, and an electron blocking layer. The light emitting layer is provided between the n-type semiconductor layer and the p-type semiconductor layer and includes a nitride semiconductor. The electron blocking layer is provided between the light emitting layer and the p-type semiconductor layer and has an aluminum composition ratio increasing from the light emitting layer toward the p-type semiconductor layer.

### CROSS-REFERENCE TO RELATED APPLICATIONS

This application is based upon and claims the benefit of priority from the prior Japanese Patent Application No. 2011-206425, filed on Sep. 21, 2011; the entire contents of which are incorporated herein by reference.

### FIELD

Embodiments described herein relate generally to a semiconductor light emitting device.

### BACKGROUND

A semiconductor light emitting device such as a light emitting diode (LED) generates light by recombination of electrons and holes. Thus, the semiconductor light emitting device is a light source with greater energy conservation and longer lifetime than filament light sources. Furthermore, the semiconductor light emitting device can generate light at various wavelengths. For instance, a light emitting device made of nitride semiconductor can emit light at a short wavelength region including blue.

Such a light emitting device made of nitride semiconductor is based on the multi-quantum well (MQW) structure in which a plurality of well layers and barrier layers are stacked to increase the light emission efficiency. The MQW structure has high efficiency at low current. However, in the MQW structure, the quantum efficiency tends to decrease at high current (efficiency droop).

### BRIEF DESCRIPTION OF THE DRAWINGS

FIG. 1 is a schematic sectional view illustrating a semiconductor light emitting device according to the first embodiment;

FIG. 2 is a schematic sectional view illustrating a light emitting layer in the semiconductor light emitting device;

FIG. 3 is a distribution diagram of the aluminum composition ratio around the electron blocking layer in the semiconductor light emitting device;

FIG. 4 is an energy band diagram around the electron blocking layer in the semiconductor light emitting device; and

FIG. 5 is a characteristic diagram illustrating the relationship between the internal quantum efficiency and the current density of the semiconductor light emitting device.

### DETAILED DESCRIPTION

In general, according to one embodiment, a semiconductor light emitting device includes an n-type semiconductor layer, a p-type semiconductor layer, a light emitting layer, and an electron blocking layer. The light emitting layer is provided between the n-type semiconductor layer and the p-type semiconductor layer and includes a nitride semiconductor. The electron blocking layer is provided between the light emitting layer and the p-type semiconductor layer and has an aluminum composition ratio increasing from the light emitting layer toward the p-type semiconductor layer.

Embodiments will now be described in detail with reference to the drawings. The drawings are schematic or conceptual. The shape and the relationship between the length and width dimensions of each portion, and the size ratio between the portions, for instance, are not necessarily identical to those in reality. Furthermore, the same portion may be shown with different dimensions or ratios depending on the figures. In the present specification and the drawings, components similar to those described previously with reference to earlier figures are labeled with like reference numerals, and the detailed description thereof is omitted appropriately.

First, a first embodiment is described.

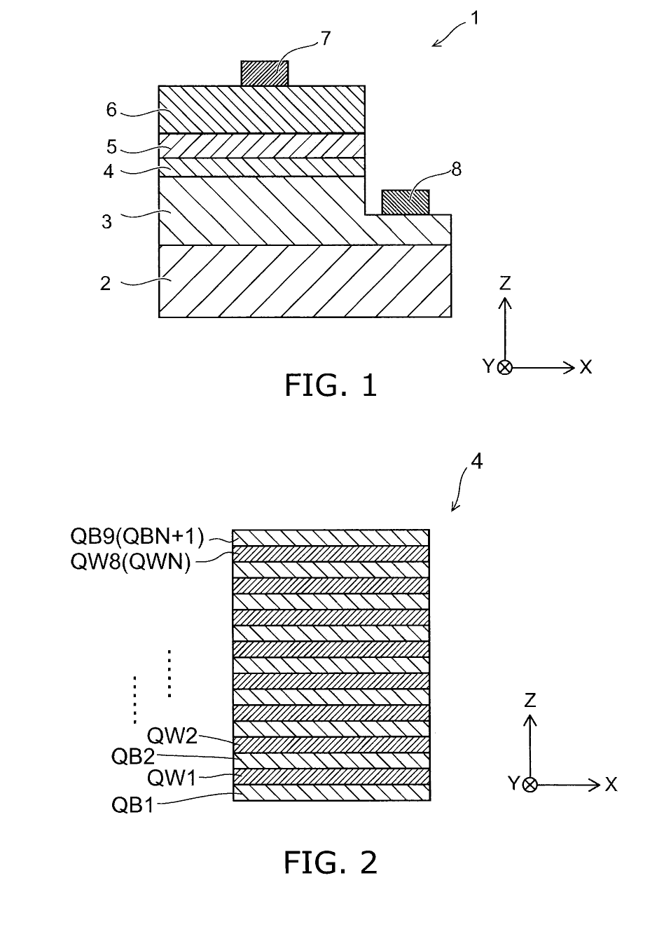

FIG. 1 is a schematic sectional view illustrating a semiconductor light emitting device according to the first embodiment.

FIG. 2 is a schematic sectional view illustrating a light emitting layer in the semiconductor light emitting device.

The semiconductor light emitting device 1 includes an n-type semiconductor layer 3 provided on a substrate 2, a light emitting layer 4 for emitting light by recombination of electrons and holes, an electron blocking layer 5 for preventing the overflowing of electrons injected into the light emitting layer 4, and a p-type semiconductor layer 6. Furthermore, the semiconductor light emitting device 1 includes a p-side electrode 7 connected to the p-type semiconductor layer 6, and an n-side electrode 8 connected to the n-type semiconductor layer 3. The semiconductor light emitting device 1 is a light emitting diode for emitting light by a current flowing between the p-side electrode 7 and the n-side electrode 8.

The substrate 2 is e.g. a sapphire substrate. The substrate 2 is used for growth of a nitride semiconductor layer such as the n-type semiconductor layer 3. The sapphire substrate is a crystal body having Hexa-Rhombo R3c symmetry. The lattice constants in the c-axis and a-axis directions are 13.001 Å and 4.758 Å, respectively. The sapphire substrate has e.g. a c-plane (0001), an a-plane (1120), and an r-plane (1102). On the above c-plane, growth of a nitride thin film is relatively easy and stable at high temperature. Thus, the sapphire substrate is primarily used as a nitride growth substrate. Here, instead of the sapphire substrate, the substrate 2 may be a substrate made of e.g. SiC, Si, GaN, or AlN.

The axis perpendicular to the major surface of the substrate 2 is defined as Z axis. One axis perpendicular to the Z axis is defined as X axis. The axis perpendicular to the Z axis and the X axis is defined as Y axis. In the following description, directions are represented by using the X, Y, and Z axes.

The n-type semiconductor layer 3 is provided on the substrate 2. The n-type semiconductor layer 3 is made of a semiconductor represented by the composition formula Al_{y}In_{z}Ga_{1-y-z}N (0≦y≦1, 0≦z≦1, 0≦y+z≦1), and includes a nitride semiconductor doped with n-type impurity. The n-type semiconductor layer 3 is e.g. GaN, AlGaN, or InGaN. The n-type impurity is e.g. Si, Ge, Se, Te, or C.

The n-type semiconductor layer 3 can be formed by e.g. metal organic chemical vapor deposition (MOCVD), molecular beam epitaxy (MBE), and hybrid vapor phase epitaxy (HVPE). Here, the n-type semiconductor layer 3 can be provided on the substrate 2 via a buffer layer, not shown.

The light emitting layer 4 is provided between the n-type semiconductor layer 3 and the p-type semiconductor layer 6. The light emitting layer 4 includes N+1 (N being a natural number) barrier layers QBn (n=1, . . . , N+1) and N well layers QWn respectively provided between the barrier layer QBn and the barrier layer QBn+1. That is, the light emitting layer 4 has a structure in which barrier layers QBn (n=2, . . . , N) and well layers QWn are alternately and repetitively stacked between the barrier layer QB1 and the barrier layer QBN+1. As illustrated in FIG. 2, the light emitting layer 4 in this embodiment has a pair number of N=8. That is, eight pairs of barrier layers QBn and well layers QWn are stacked between the barrier layer QB1 and the barrier layer QB9. However, the pair number N is not limited to N=8, but can be set to e.g. N=5-10.

The barrier layer QBn includes a nitride semiconductor having the composition formula Al_{y}In_{z}Ga_{1-y-z}N (0≦y≦1, 0≦z≦1, 0≦y+z≦1). The well layer QWn includes a nitride semiconductor having the composition formula In_{z}Ga_{1-z}N (0≦z≦1). The barrier layer QBn is e.g. GaN. The well layer QWn is e.g. In_{0.2}Ga_{0.8}N.

The well layer QWn has a higher In composition ratio than the barrier layer QBn. Thus, the bandgap of the well layer QWn is narrower than the bandgap of the barrier layer QBn. As a result, each well layer QWn separately constitutes a quantum well between the barrier layer QBn and the barrier layer QBn+1. In the light emitting layer 4, N pairs of barrier layers QBn and well layers QWn are stacked. Thus, the light emitting layer 4 constitutes a multi-quantum well (MQW).

The barrier layer QBn and the well layer QWn can be formed by e.g. metal organic chemical vapor deposition (MOCVD), molecular beam epitaxy (MBE), and hybrid vapor phase epitaxy (HVPE) like the n-type semiconductor layer 3.

The light emitting layer 4 can be provided on the n-type semiconductor layer 3 via a superlattice layer (not shown) constituting a superlattice. For instance, InₓGaN with the In ratio (x) smaller than that of the light emitting layer 4 (x<z) can be alternately stacked with GaN to provide a superlattice layer. This can reduce lattice strain in the light emitting layer 4 and suppress the decrease of the light emission efficiency.

The electron blocking layer 5 is provided between the light emitting layer 4 and the p-type semiconductor layer 6. The electron blocking layer 5 includes a nitride semiconductor having the composition formula AlₓGa₁₋ₓN (0≦x≦1). The electron blocking layer 5 has a wider bandgap Eb than other layers such as the light emitting layer 4 and the p-type semiconductor layer 6. Thus, the electron blocking layer 5 serves as a barrier against electrons flowing from the light emitting layer 4 to the p-type semiconductor layer 6. Hence, electrons injected from the n-type semiconductor layer 3 are prevented from overflowing to the p-type semiconductor layer 6. Thus, the electrons can be confined in the light emitting layer 4.

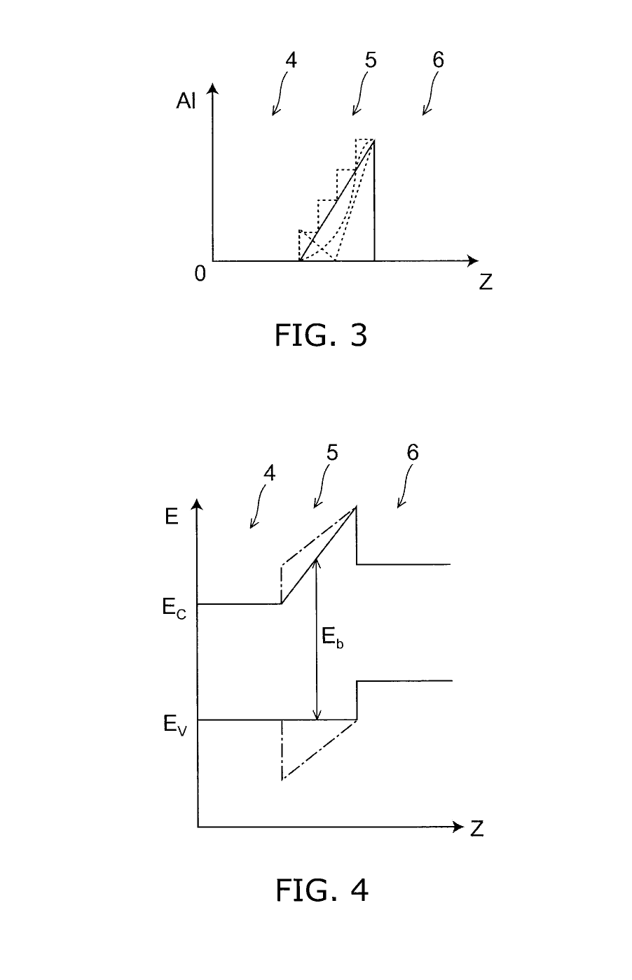

FIG. 3 is a distribution diagram of the aluminum composition ratio around the electron blocking layer in the semiconductor light emitting device.

FIG. 4 is an energy band diagram around the electron blocking layer in the semiconductor light emitting device.

In FIG. 3, the horizontal axis is taken as the Z axis to represent the position in the thickness direction around the electron blocking layer 5. The vertical axis schematically represents the aluminum (Al) composition ratio around the electron blocking layer 5. In FIG. 4, the horizontal axis is taken as the Z axis, and the vertical axis represents energy E. The energy band is shown by solid lines. For comparison, the energy band for a uniform aluminum (Al) composition ratio is shown by dot-dashed lines.

The aluminum composition ratio of the electron blocking layer 5 is increased toward the positive direction of the Z axis, i.e., from the light emitting layer 4 toward the p-type semiconductor layer 6. The bandgap Eb=Ec−Ev of the electron blocking layer 5 has a structure of being narrow on the light emitting layer 4 side, widening from the light emitting layer 4 toward the p-type semiconductor layer 6, and being widest on the p-type semiconductor layer 6 side (solid lines in FIG. 4). As a result, compared to the case where the aluminum (Al) composition ratio of the electron blocking layer 5 is constant (dot-dashed lines in FIG. 4), the efficiency of hole injection into the light emitting layer 4 can be increased without compromising the capability of blocking electrons. Here, Ec denotes the energy of the conduction band edge, and Ev denotes the energy of the valence band edge.

Here, the example shown by a solid line in FIG. 3 illustrates a configuration in which the aluminum composition ratio of the electron blocking layer 5 is increased linearly from the light emitting layer 4 toward the p-type semiconductor layer 6. However, this embodiment is not limited thereto. That is, the aluminum composition ratio only needs to be increased from the light emitting layer 4 toward the p-type semiconductor layer 6. The increase does not necessarily need to be linear, but may be e.g. stepwise or curvilinear (dashed lines in FIG. 3). Furthermore, the aluminum composition ratio does not need to be increased monotonically from the light emitting layer 4 toward the p-type semiconductor layer 6. For instance, as shown by a dashed line in FIG. 3, the aluminum composition ratio of the electron blocking layer 5 may be decreased toward the positive direction of the Z axis, minimized in the electron blocking layer 5, and further increased toward the positive direction of the Z axis.

Returning to FIG. 1, the p-type semiconductor layer 6 is provided on the electron blocking layer 5.

The p-type semiconductor layer 6 includes a nitride semiconductor having the composition formula Al_{y}In_{z}Ga_{1-y-z}N (0≦y≦1, 0≦z≦1, 0≦y+z≦1) and doped with p-type impurity. The p-type semiconductor layer 6 is e.g. GaN, AlGaN, or InGaN. The p-type impurity is e.g. Mg, Zn, or Be.

The p-type semiconductor layer 6 can be formed by e.g. metal organic chemical vapor deposition (MOCVD), molecular beam epitaxy (MBE), and hybrid vapor phase epitaxy (HVPE) like the n-type semiconductor layer 3.

The p-side electrode 7 is provided on the p-type semiconductor layer 6 and electrically connected to the p-type semiconductor layer 6. Here, the p-side electrode 7 can be provided on the p-type semiconductor layer 6 via a current spreading layer, not shown.

The n-side electrode 8 is provided on the n-type semiconductor layer 3 and electrically connected to the n-type semiconductor layer 3. For instance, by using the RIE (reactive ion etching) method, a mesa structure is formed in the n-type semiconductor layer 3, the light emitting layer 4, the electron blocking layer 5, and the p-type semiconductor layer 6. The n-side electrode 8 is provided on the etching surface of the n-type semiconductor layer 3 exposed at the bottom surface of the mesa groove.

A current is passed between the p-side electrode 7 and the n-side electrode 8. Thus, to the well layer QWn of the light emitting layer 4, electrons are injected from the n-type semiconductor layer 3, and holes are injected from the p-type semiconductor layer 6 via the electron blocking layer 5. Upon recombination of the injected electrons and holes, the light emitting layer 4 emits light.

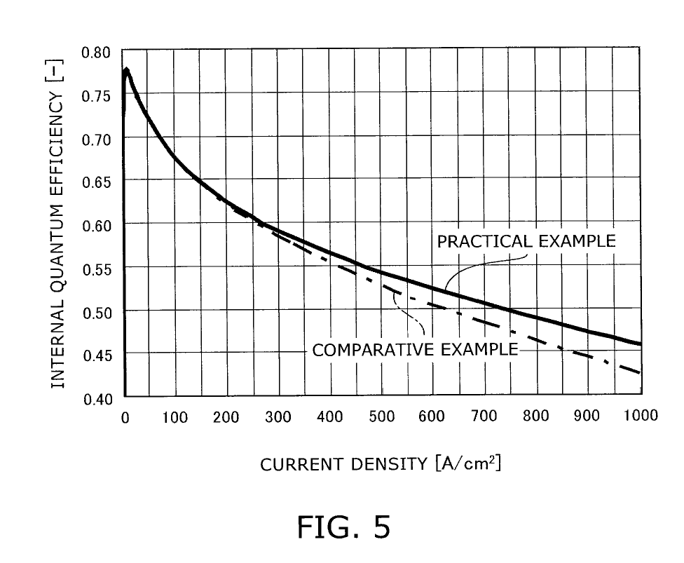

FIG. 5 is a characteristic diagram illustrating the relationship between the internal quantum efficiency and the current density of the semiconductor light emitting device.

In FIG. 5, for two cases with different configurations of the electron blocking layer 5, the simulation result of the relationship between the internal quantum efficiency and the current density is shown by the solid line and the dot-dashed line. As a practical example, the configuration with the aluminum composition ratio of the electron blocking layer 5 increasing from the light emitting layer 4 toward the p-type semiconductor layer 6 is shown by the solid line. As a comparative example, the configuration with the aluminum composition ratio of the electron blocking layer 5 being uniform is shown by the dot-dashed line.

The condition for the simulation in the above practical example is as follows.

The n-type semiconductor layer 3 is made of n-type GaN having a thickness of 100 nm and doped with Si to a carrier concentration of 1×10¹⁸ cm⁻³. The well layer QWn is made of In_{0.15}Ga_{0.85}N having a thickness of 2.5 nm. The barrier layer QBn is made of GaN having a thickness of 10 nm. The light emitting layer 4 is configured by stacking five pairs of the above well layers QWn and barrier layers QBn. Between the n-type semiconductor layer 3 and the light emitting layer 4, a superlattice layer is provided. In the superlattice layer, 20 pairs of In_{0.05}Ga_{0.95}N having a thickness of 1 nm and GaN having a thickness of 1 nm are stacked. The electron blocking layer 5 is made of AlₓGa₁₋ₓN (0.01≦x≦0.2) having a thickness of 10 nm. The p-type semiconductor layer 6 is made of p-type GaN having a thickness of 100 nm and doped with Mg to a carrier concentration of 1×10¹⁸ cm⁻³. Between the p-type semiconductor layer 6 and the p-side electrode 7, a current spreading layer made of ITO having a thickness of 100 nm is provided.

As shown in FIG. 5, the practical example with the aluminum composition ratio of the electron blocking layer 5 increasing from the light emitting layer 4 toward the p-type semiconductor layer 6 has a higher internal quantum efficiency than the comparative example with a uniform aluminum composition ratio. That is, although the internal quantum efficiency tends to decrease at high current (efficiency droop), the practical example generally has a higher internal quantum efficiency than the comparative example.

In the practical example, the aluminum composition ratio of the electron blocking layer 5 is increased from the light emitting layer 4 toward the p-type semiconductor layer 6. The bandgap Eb of the electron blocking layer 5 has a structure of being narrow on the light emitting layer 4 side, widening from the light emitting layer 4 toward the p-type semiconductor layer 6, and being widest on the p-type semiconductor layer 6 side (solid lines in FIG. 5). As a result, it is considered that compared to the case where the aluminum (Al) composition ratio of the electron blocking layer 5 is constant (dot-dashed lines in FIG. 5), the efficiency of hole injection into the light emitting layer 4 is increased without compromising the capability of blocking electrons.

Here, it is also considered that increasing the aluminum composition ratio of the electron blocking layer 5 from the light emitting layer 4 toward the p-type semiconductor layer 6 results in thinning the effective (electrical) film thickness of the electron blocking layer 5. For instance, in the case where a high voltage is applied to the light emitting layer 4, electrons reaching the electron blocking layer 5 have high energy. This may increase the overflow current due to tunneling current. However, in this case, it is considered that by increasing the film thickness of the electron blocking layer 5, the capability of blocking electrons can be ensured, and the hole injection efficiency can also be maintained.

Next, the effect of this embodiment is described.

In this embodiment, the aluminum composition ratio of the electron blocking layer 5 is increased from the light emitting layer 4 toward the p-type semiconductor layer 6. As a result, the efficiency of hole injection into the light emitting layer 4 can be increased without compromising the capability of blocking electrons. Thus, the light emission efficiency can be improved.

On the other hand, in AlN, the activation energy of acceptors is high. Thus, acceptors are difficult to activate. This may decrease the hole concentration.

In this embodiment, as an electron blocking layer 5, a layer having low aluminum concentration is placed on the light emitting layer 4 side. This facilitates activating acceptors, and can increase the hole concentration around the light emitting layer 4. Thus, the internal quantum efficiency can be increased, and the light emission efficiency can be improved.

Furthermore, in this embodiment, between the light emitting layer 4 and the p-type semiconductor layer 6, the electron blocking layer 5 is formed with the composition gradually changed. As a result, defects such as dislocations due to lattice mismatch are less likely to occur. Thus, the internal quantum efficiency can be increased, and the light emission efficiency can be improved.

In the configuration of this embodiment illustrated above, the electron blocking layer 5 is made of AlGaN including aluminum. However, the electron blocking layer 5 may be made of other nitride semiconductors or wide bandgap materials.

In this description, the “nitride semiconductor” includes group III-V compound semiconductors of BₓIn_{y}Al_{z}Ga_{1-x-y-z}N (0≦x≦1, 0≦y≦1, 0≦z≦1, 0≦x+y+z≦1). Furthermore, the “nitride semiconductor” includes mixed crystals containing e.g. phosphorus (P) or arsenic (As) in addition to N (nitrogen) as group V elements.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor light emitting device comprising:
an n-type semiconductor layer;
a p-type semiconductor layer;
a light emitting layer provided between the n-type semiconductor layer and the p-type semiconductor layer and including a nitride semiconductor; and
an electron blocking layer provided between the light emitting layer and the p-type semiconductor layer and having an aluminum composition ratio increasing from the light emitting layer toward the p-type semiconductor layer.

2. The device according to claim 1, wherein the aluminum composition ratio of the electron blocking layer on the light emitting layer side is zero.

3. The device according to claim 1, wherein the aluminum composition ratio of the electron blocking layer increases linearly from the light emitting layer toward the p-type semiconductor layer.

4. The device according to claim 1, wherein the aluminum composition ratio of the electron blocking layer increases curvilinearly from the light emitting layer toward the p-type semiconductor layer.

5. The device according to claim 1, wherein the aluminum composition ratio of the electron blocking layer increases stepwise from the light emitting layer toward the p-type semiconductor layer.

6. The device according to claim 1, wherein the aluminum composition ratio of the electron blocking layer decreases from the light emitting layer toward the p-type semiconductor layer, is minimized in the electron blocking layer, and further increases toward the p-type semiconductor layer.

7. The device according to claim 1, wherein the electron blocking layer is made of Al_{y}In_{z}Ga_{1-y-z}N (0≦y≦1, 0≦z≦1, 0≦y+z≦1).

8. The device according to claim 1, wherein the n-type semiconductor layer includes a nitride semiconductor represented by composition formula Al_{y}In_{z}Ga_{1-y-z}N (0≦y≦1, 0≦z≦1, 0≦y+z≦1).

9. The device according to claim 1, wherein the light emitting layer includes a structure of stacking:
a plurality of barrier layers; and
a plurality of well layers respectively provided between the plurality of barrier layers and having a narrower bandgap than the plurality of barrier layers.

10. The device according to claim 9, wherein each of the plurality of barrier layers includes a nitride semiconductor represented by composition formula Al_{y}In_{z}Ga_{1-y-z}N (0≦y≦1, 0≦z≦1, 0≦y+z≦1).

11. The device according to claim 9, wherein each of the plurality of barrier layers is made of GaN.

12. The device according to claim 9, wherein each of the plurality of well layers includes a nitride semiconductor represented by composition formula In_{z}Ga_{1-z}N (0≦z≦1).

13. The device according to claim 9, wherein each of the plurality of well layers is made of In_{0.2}Ga_{0.8}N.

14. The device according to claim 9, wherein the n-type semiconductor layer includes a nitride semiconductor represented by composition formula Al_{y}In_{z}Ga_{1-y-z}N (0≦y≦1, 0≦z≦1, 0≦y+z≦1).

15. The device according to claim 14, wherein the n-type semiconductor layer includes at least one of Si, Ge, Se, Te, and C as n-type impurity.

16. The device according to claim 9, wherein the p-type semiconductor layer includes a nitride semiconductor represented by composition formula Al_{y}In_{z}Ga_{1-y-z}N (0≦y≦1, 0≦z≦1, 0≦y+z≦1).

17. The device according to claim 16, wherein the p-type semiconductor layer includes at least one of Mg, Zn, and Be as p-type impurity.

18. The device according to claim 1, further comprising:
a substrate made of at least one of sapphire, SiC, Si, GaN, and AlN,
wherein the n-type semiconductor layer is provided on the substrate.

19. The device according to claim 1, further comprising:
a p-side electrode provided on the p-type semiconductor layer and electrically connected to the p-type semiconductor layer.

20. The device according to claim 1, further comprising:
a n-side electrode provided on the n-type semiconductor layer and electrically connected to the n-type semiconductor layer.
